(19) United States
(12) Patent Application Publication
(10) Pub. No.: US 2025/0204218 A1
(43) Pub. Date: Jun. 19, 2025

(54) Display Device

(71) Applicant: LG Display Co., Ltd., Seoul (KR)

(72) Inventors: Hanseok Lee, Paju-si (KR); Daehee Kim, Paju-si (KR)

(21) Appl. No.: 18/815,690

(22) Filed: Aug. 26, 2024

(30) Foreign Application Priority Data
Dec. 15, 2023 (KR) 10-2023-0183677

(51) Int. Cl. H10K 59/80; G09G 3/3233; H10K 59/122

(52) U.S. Cl. CPC H10K 59/873; H10K 59/122; G09G 3/3233; G09G 2300/0842; G09G 2354/00

(57) ABSTRACT

A display device presented herein may include a substrate, a planarization layer on the substrate, a dam separated from the planarization layer, a first encapsulation layer that covers the dam, and a first coating layer on the first encapsulation layer. The first coating layer overlaps the dam, thereby preventing or at least reducing the moisture penetration.

### CROSS-REFERENCE TO RELATED APPLICATION

This application claims the priority from Republic of Korea Patent Application No. 10-2023-0183677, filed on Dec. 15, 2023, which is hereby incorporated by reference in its entirety.

### BACKGROUND

### Field

Embodiments of the present disclosure relate to a display device.

### Description of Related Art

As the information society develops, there is increasing the demand for display devices for displaying images in various forms. Therefore, in recent years, there have been used various display devices such as liquid crystal displays and organic light emitting display devices.

A display device may include a display area and a non-display area.

### SUMMARY

Moisture may penetrate into a display panel through the non-display area.

Embodiments of the present disclosure may provide a display device capable of preventing or at least reducing moisture penetration.

Embodiments of the present disclosure may provide a display device which can prevent or at least reduce seams formed in a display panel.

Embodiments of the present disclosure can provide a display device capable of lengthening a moisture permeable path.

Embodiments of the present disclosure can provide a display device capable of low power consumption by preventing or at least reducing moisture penetration.

A display device according to one or more embodiments of the present disclosure may include a substrate including a display area, and a dam area that is an outer area of the display area, a planarization layer on the substrate, a dam on the substrate and in the dam area, a first encapsulation layer that covers the planarization layer and the dam, and a first coating layer on the first encapsulation layer and in the dam area.

The first coating layer may be outside a lower portion of the planarization layer.

The first coating layer may be outside an inner lower portion of the dam.

The display device may further include a bank between the first encapsulation layer and the planarization layer, and the first coating layer may be outside a lower portion of the bank.

The display device may further include a second coating layer outside a lower portion of the dam.

The first coating layer may include a fluorine-based material.

Embodiments of the present disclosure may provide a display device capable of preventing or at least reducing moisture penetration.

Embodiments of the present disclosure may provide a display device capable of preventing or at least reducing seams which may be formed on a display panel.

Embodiments of the present disclosure may provide a display device with improved encap performance by forming a long moisture permeable path.

Embodiments of the present disclosure may provide a display device capable of low power consumption by preventing or at least reducing moisture penetration.

### BRIEF DESCRIPTION OF THE DRAWINGS

FIG. 1 is a system configuration diagram of a display device according to one or more embodiments of the present disclosure.

FIG. 2 illustrates a display panel according to one or more embodiments of the present disclosure.

FIG. 3 illustrates a substrate of a display panel according to one or more embodiments of the present disclosure.

FIG. 4 is a cross-sectional view of a display area of a display panel according to one or more embodiments of the present disclosure.

FIG. 5 is a cross-sectional view of a dam area of a display device according to one or more embodiments of the present disclosure.

FIG. 6 is a cross-sectional view of a dam area of a display device according to one or more embodiments of the present disclosure.

FIG. 7 is a cross-sectional view of a dam area of a display device according to one or more embodiments of the present disclosure.

FIGS. 8, 9 and 10 are diagrams for explaining the process of forming a coating layer according to one or more embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “comprising”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure are described in detail with reference to the accompanying drawings.

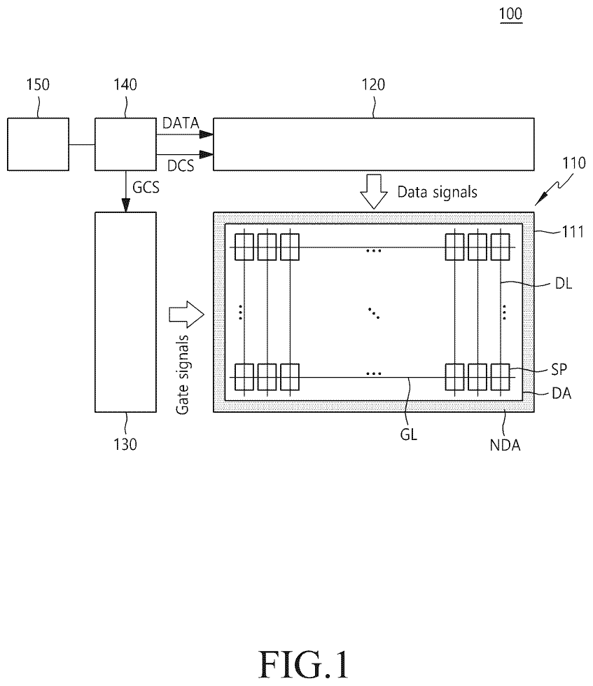

FIG. 1 is a system configuration diagram of a display device 100 according to one or more embodiments of the present disclosure.

Referring to FIG. 1, a display device 100 according to one or more embodiments of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

A plurality of subpixels SP for image display may be disposed in the display area DA, and the non-display area NDA may include a pad area PA located in the first direction from the display area DA.

In a display panel 110 according to one or more embodiments of the present disclosure, the non-display area NDA may be very small. In this specification, the non-display area NDA may be also referred to as a “bezel.”

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three which do not include the pad area may be very small in size.

For another example, a boundary area between the display area DA and the non-display area NDA may be bent so that the non-display area NDA may be located below the display area. In this case, when the user looks at the display device 100 from the front, there may be little or no non-display area NDA visible to the user.

Various types of signal lines for driving a plurality of subpixels SP may be disposed on the substrate 111 of the display panel 110.

The display device 100 according to one or more embodiments of the present disclosure may be a liquid crystal display device or the like, or may be a self-luminous display device in which the display panel 110 emits light by itself. When the display device 100 according to one or more embodiments of the present disclosure is a self-luminous display device, each of the plurality of subpixels SP may include a light emitting device.

For example, the display device 100 according to one or more embodiments of the present disclosure may be an organic light emitting display device in which a light emitting device is implemented as an organic light emitting diode (OLED). For another example, the display device 100 according to one or more embodiments of the present disclosure may be an inorganic light emitting display device in which the light emitting device is implemented as an inorganic-based light emitting diode. For another example, the display device 100 according to one or more embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a colu mn direction. Hereinafter, for convenience of explanation, it will exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data ines DL.

For example, the data driving circuita 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to one or more embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display device 100 according to one or more embodiments of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA).

In the present disclosure, a gate driving circuit 130 built into the display panel 110 as a gate-in-panel type may be referred to as a “gate-in-panel circuit.”

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, etc., and may be electrically connected to the data driving circuit 120 and the gate driving circuit 130 through a printed circuit board, a flexible printed circuit.

The display controller 240 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI).

In order to provide not only an image display function but also a touch sensing function, the display device 100 according to one or more embodiments of the present disclosure may include a touch sensor and a touch sensing circuit for detecting an occurrenace of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate SUB along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit 260 may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit and the data driving circuit may be implemented as separate devices or as one device.

The display device 100 may further include a power supply circuit which supplies various types of power to the display driving circuit and/or the touch sensing circuit.

The display device 100 according to one or more embodiments of the present disclosure may be a mobile terminal such as a smart phone or tablet, or a monitor or television of various sizes, but is not limited thereto, and may be a display of various types and sizes capable of displaying information or images.

The display device 100 according to one or more embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

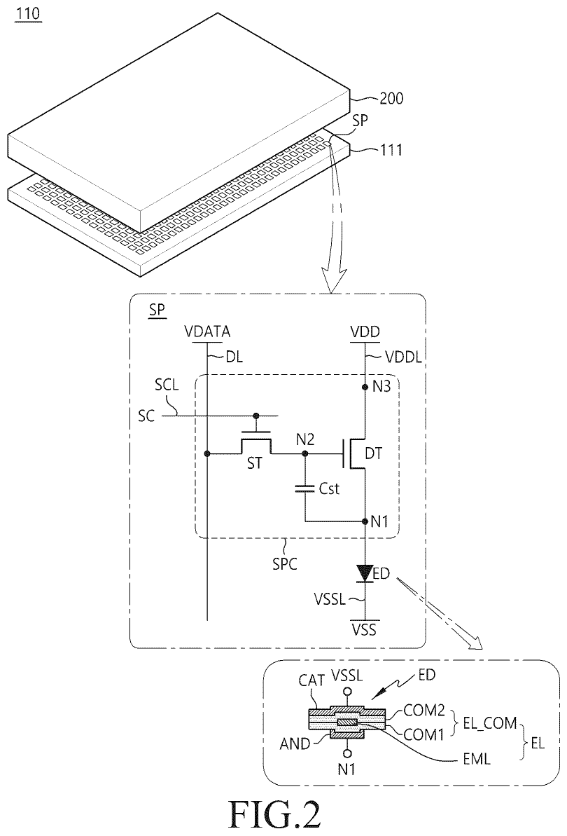

FIG. 2 illustrates a display panel 110 according to one or more embodiments of the present disclosure.

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to one or more embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common pixel driving voltage including a first driving voltage VDD and a second driving voltage VSS may be applied to the subpixel SP in order to drive the subpixel SP.

The light emitting device ED may include an anode AND, a light emitting device intermediate layer EL, and a cathode CAT. The light emitting device intermediate layer EL may be a layer disposed between the anode AND and the cathode CAT.

In the case that the light emitting device ED is an organic light emitting device, the light emitting device intermediate layer EL may include an emission layer EML, a first common intermediate layer COM1 between the anode AND and the emission layer EML, and a second common intermediate layer COM2 between the emission layer EML and the cathode. The emission layer EML may be disposed in each subpixel SP. In comparison, the first common intermediate layer COM1 and the second common intermediate layer COM2 may be commonly disposed across a plurality of subpixels SP. The emission layer EML may be disposed in each emission area, and the first common intermediate layer COM1 and the second common intermediate layer COM2 may be commonly disposed across a plurality of emission areas and non-emission areas. The first common intermediate layer COM1 and the second common intermediate layer COM2 may be collectively referred to as a common intermediate layer EL_COM.

For example, the first common intermediate layer COM1 may include a hole injection layer HIL and a hole transport layer HTL. The second common intermediate layer COM2 may include an electron transport layer ETL and an electron injection layer EIL. The hole injection layer may inject holes from the anode AND to the hole transport layer, the hole transport layer may transport holes to the emission EML, the electron injection layer may inject electrons from the cathode CAT to the electron transport layer, and the electron transport layer may transport electrons to the emission layer EML.

For example, the cathode CAT may be electrically connected to a second common driving voltage line VSSL. A second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line VSSL.

For example, the anode AND may be a pixel electrode disposed in each subpixel SP, and the cathode CAT may be a common electrode commonly disposed in a plurality of subpixels SP. For another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of an anode AND, a light emitting device intermediate layer EL and a cathode CAT. A predetermined emissoin area may be formed by each light emitting device ED. For example, the emission area of each light emitting device ED may include an area where the anode AND, the light emitting device intermediate layer EL and the cathode CAT overlap.

For example, the light emitting device ED may be an organic light emitting diode (OLED), an inorganic light emitting diode, or a quantum dot light emitting device. For example, in the case that the light emitting device ED is an organic light emitting diode OLED, the light emitting device intermediate layer EL in the light emitting device ED may include an organic light emitting device intermediate layer EL containing an organic material.

The driving transistor DT may be a driving transistor for supplying driving current to the light emitting device ED. The driving transistor DT may be connected between a first common driving voltage line VDDL and the light emitting device ED.

The driving transistor DT may include a first node N1 electrically connected to the light emitting device ED, a second node N2 to which the data signal VDATA is applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Alternatively, if the display panel 110 has a bottom emission structure, the subpixel circuit SPC may not overlap with the light emitting device ED in the vertical direction.

As shown in FIG. 2, the subpixel circuit SPC may have 2T-1C structure including two transistors T1 and T2 and one capacitor Cst. In some cases, the subpixel circuit SPC may further include one or more transistors or one or more capacitors.

For example, the subpixel circuit SPC may have a 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent or at least reduce oxygen from penetrating into the circuit elements (particularly, the light emitting device ED). The encapsulation layer 200 may be configured in various shapes to prevent the light emitting device ED from coming into contact with moisture or oxygen.

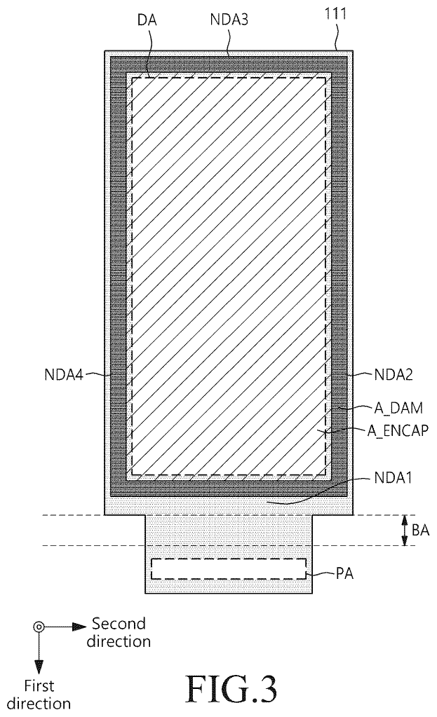

FIG. 3 illustrates a substrate 111 of a display panel 110 according to one or more embodiments of the present disclosure.

Referring to FIG. 3, the substrate 111 of the display panel 110 according to one or more embodiments of the present disclosure may include a display area DA in which an image is displayed and a non-display area NDA in which an image is not displayed.

Referring to FIG. 3, the non-display area NDA may include a first non-display area NDA1 located in a first direction from the display area DA, a second non-display area NDA2 located in a second direction from the display area DA, a third non-display area NDA3 located in a direction opposite to the first direction from the display area DA, and a fourth non-display area NDA4 located in a direction opposite to the second direction from the display area DA. For example, the first direction may be a column direction (e.g., Y-axis direction), and the second direction crossing the first direction may be a row direction (e.g., X-axis direction).

Referring to FIG. 3, the first non-display area NDA1 may include a pad area PA where a plurality of pads are disposed.

There may be disposed a plurality of pads to which the driving circuit is electrically connected in the pad area PA. A plurality of driving circuits or printed circuit boards may be electrically connected in the pad area. For example, the plurality of pads may include a plurality of display pads and a plurality of touch pads. A plurality of data lines, a first common driving voltage line VDDL, a second common driving voltage line VSSL may be electrically connected to the plurality of display pads. A plurality of touch routing lines TL may be electrically connected to the plurality of touch pads.

Referring to FIG. 3, the first non-display area NDA1 may further include a bending area BA. In this case, the substrate 111 may be a flexible substrate. In some cases, the first non-display area NDA1 may not include the bending area BA.

Referring to FIG. 3, the display panel 110 may further include a ground line disposed in the non-display area NDA of the substrate 111. The ground line may be disposed from one point in the pad area PA to another point in the pad area PA via the second non-display area NDA2, the third non-display area NDA3, and the fourth non-display area NDA4.

Referring to FIG. 3, the display panel 110 may include an encapsulation layer area A_ENCAP and a dam area A_DAM.

Referring to FIG. 3, the encapsulation layer area A_ENCAP may be an area where the encapsulation layer 200 is disposed. In the display panel 110 according to one or more embodiments of the present disclosure, the encapsulation layer 200 may have a structure in which an inorganic layer and an organic layer are stacked. In this case, an edge of the encapsulation layer 200 may be referred as an edge of the organic layer.

Referring to FIG. 3, the dam area A_DAM may be an area surrounding the encapsulation layer area A_ENCAP. There may be located a structure for providing a dam function in the dam area A_DAM. A dam may prevent liquid organic films from flowing outward.

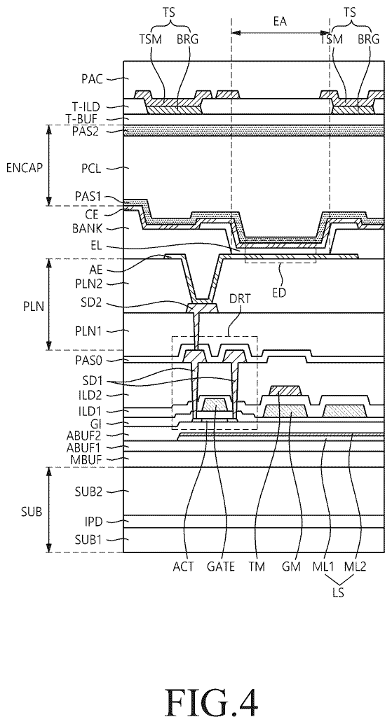

FIG. 4 is a cross-sectional view of a display area DA of a display panel 110 according to one or more embodiments of the present disclosure.

Referring to FIG. 4, a substrate SUB may include a first substrate SUB1, an interlayer insulating film IPD, and a second substrate SUB2. The interlayer insulating film IPD may be located between the first substrate SUB1 and the second substrate SUB2. Since the substrate SUB is composed of the first substrate SUB1, the interlayer insulating film IPD and the second substrate SUB2, it is possible to prevent or at least reduce moisture penetration. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Referring to FIG. 4, there may be disposed various patterns (e.g., ACT1, SD1 and GATE1) and various insulating films (e.g., MBUF, ABUF1, ABUF2, GI, ILD1, ILD2 and PAS0) and various metal patterns (e.g., TM1, GM, ML1 and ML2) on the substrate SUB.

Referring to FIG. 4, a multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. Here, the first metal layer ML1 and the second metal layer ML2 may be a light shield layer for shielding light.

A second active buffer layer ABUF2 may be disposed on the first metal layer ML1 and the second metal layer ML2. A first active layer ACT1 of the driving transistor DRT may be disposed on the second active buffer layer ABUF2.

A first gate insulating film GI1 may be disposed while covering the first active layer ACT1.

A first gate electrode GATE1 of the driving transistor DRT may be disposed on the first gate insulating film GI1. In this case, a gate material layer GM may be disposed on the first gate insulating film GI1 together with the first gate electrode GATE1 of the driving transistor DRT at a position different from the formation position of the driving transistor DRT.

A first interlayer insulating film ILD1 may be disposed while covering the first gate electrode GATE1 and the gate material layer GM. A metal pattern TM1 may be disposed on the first interlayer insulating film ILD1. The metal pattern TM1 may be located at a location different from the formation location of the driving transistor DRT. A second interlayer insulating film ILD2 may be disposed while covering the metal pattern TM1 on the first interlayer insulating film ILD1.

Two first source-drain electrode patterns SD1 may be disposed on the second interlayer insulating film ILD2. One of the two first source-drain electrode patterns SD1 may be a source node of the driving transistor DRT, and the other may be a drain node of the driving transistor DRT. The two first source-drain electrode patterns SD1 may be electrically connected to one side and the other side of the first active layer ACT1 through a contact hole in the second interlayer insulating film ILD2, the first interlayer insulating film ILD1 and the first gate insulating film GI1.

A portion of the first active layer ACT1 which overlaps with the first gate electrode GATE1 may be a channel area. One of the two first source-drain electrode patterns SD1 may be connected to one side of the channel area in the first active layer ACT1, and the other one of the two first source-drain electrode patterns SD1 may be connected to the other side of the channel area in the first active layer ACT1.

A passivation layer PAS0 may be disposed covering the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 (which corresponds to the second node N2 of the driving transistor DRT in the subpixel SP of FIG. 3) through a contact hole of the first planarization layer PLN1.

The second planarization layer PLN2 may be disposed while covering the second source-drain electrode pattern SD2. A light emitting device ED may be disposed on the second planarization layer PLN2.

In the stacked structure of the light emitting device ED, the anode electrode AE may be disposed on the second planarization layer PLN2. The anode electrode AE may be electrically connected to the second source-drain electrode pattern SD2 through a contact hole in the second planarization layer PLN2.

A bank BANK may be disposed while covering a portion of the anode electrode AE. A portion of the bank BANK corresponding to the emission area EA of the subpixel SP may be open.

A part of the anode electrode AE may be exposed to an opening (i.e., open portion) of the bank BANK. An emission layer EL may be located on the side of the bank BANK and the opening (i.e., open portion) of the bank BANK. All or part of the emission layer EL may be located between adjacent banks BANK.

At the opening of the bank BANK, the emission layer EL may contact the anode electrode AE. A cathode electrode CE may be disposed on the emission layer EL.

A light emitting device ED may be formed by an anode electrode AE, an emission layer EL and a cathode electrode CE. The emssion layer EL may include an organic layer.

An encapsulation layer ENCAP may be disposed on the light emitting device ED.

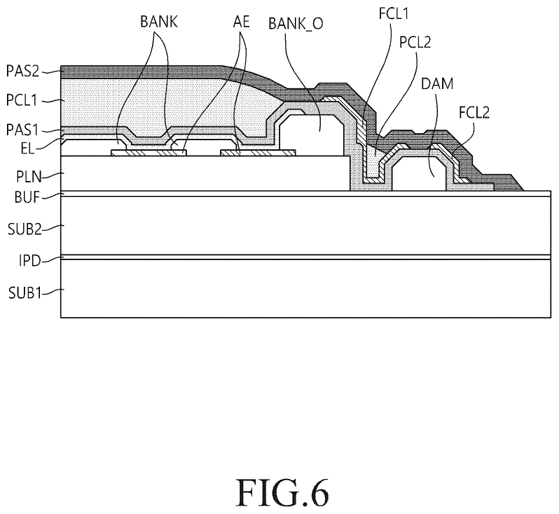

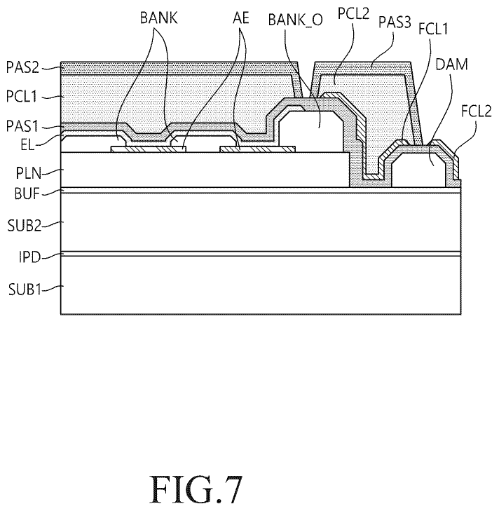

The encapsulation layer ENCAP may have a single-layer structure or a multi-layer structure. For example, as shown in FIGS. 6 and 7, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest, and may serve as a planarization layer.

The first encapsulation layer PAS1 may be disposed on the cathode electrode CE, and may be disposed closest to the light emitting device ED. The first encapsulation layer PAS1 may be formed of an inorganic insulating material capable of low-temperature deposition. For example, the first encapsulation layer PAS1 may be silicon nitride (SiNx), silicon oxide (SiOx), silicon oxynitride (SiON), or aluminum oxide (Al2O3). Since the first encapsulation layer PAS1 is deposited in a low-temperature atmosphere, the first encapsulation layer PAS1 may prevent the emission layer EL containing organic materials vulnerable to high-temperature atmospheres from being damaged during the deposition process.

The second encapsulation layer PCL may be formed to have a smaller area than the first encapsulation layer PAS1. In this case, the second encapsulation layer PCL may be formed to expose both ends of the first encapsulation layer PAS1. The second encapsulation layer PCL may serve as a buffer to relieve stress between each layer due to bending of the display device 100, and may also serve to enhance planarization performance. For example, the second encapsulation layer PCL may be acrylic resin, epoxy resin, polyimide, polyethylene, or silicon oxycarbon (SiOC), and may be formed of an organic insulating material. For example, the second encapsulation layer PCL may be formed using an inkjet method.

The third inorganic encapsulation layer PAS2 may be formed to cover an upper surface ant a side surface of each of the second encapsulation layer PCL and the first encapsulation layer PAS1 on the substrate SUB on which the second encapsulation layer PCL is formed. The third encapsulation layer PAS2 may minimize, reduce or block external moisture or oxygen from penetrating into the first inorganic encapsulation layer PAS1 and the second encapsulation layer PCL as an organic encapsulation layer. For example, the third encapsulation layer PAS2 may be formed of an inorganic insulating material such as silicon nitride (SiNx), silicon oxide (SiOx), silicon oxynitride (SiON), or aluminum oxide (Al2O3).

Referring to FIG. 4, when a touch sensor TS is a type built into the display panel PNL, the touch sensor TS may be disposed on the encapsulation layer ENCAP. The touch sensor structure is described in detail as follows.

A touch buffer film T-BUF may be disposed on the encapsulation layer ENCAP. A touch sensor TS may be disposed on the touch buffer film T-BUF.

The touch sensor TS may include touch sensor metals TSM and bridge metal BRG located in different layers.

A touch interlayer insulating film T-ILD may be disposed between the touch sensor metals TSM and the bridge metal BRG.

For example, the touch sensor metals TSM may include a first touch sensor metal TSM, a second touch sensor metal TSM, and a third touch sensor metal TSM arranged adjacent to each other. In the case that the third touch sensor metal TSM is disposed between the first touch sensor metal TSM and the second touch sensor metal TSM, and the first touch sensor metal TSM and the second touch sensor metal (TSM) are required to be electrically connected to each other, the first touch sensor metal TSM and the second touch sensor metal TSM may be electrically connected to each other through a bridge metal BRG located on a different layer. The bridge metal BRG may be insulated from the third touch sensor metal TSM by a touch interlayer insulating film T-ILD.

When the touch sensor TS is formed on the display panel PNL, there may be generated the chemical solutions (developer or etchant, etc.) used in the process or the moisture from the outside. By disposing the touch sensor TS on the touch buffer film T-BUF, chemical solutions or moisture may be prevented from penetrating into the emission layer EL containing organic materials during the manufacturing process of the touch sensor TS. Accordingly, the touch buffer film T-BUF may prevent or at least reduce damage to the emission layer EL which is vulnerable to chemicals or moisture.

The touch buffer film T-BUF may be formed at a low temperature below a specific temperature (e.g., 100 degrees Celsius) in order to prevent or at least reduce damage to the emission layer EL containing organic materials vulnerable to high temperatures, and may be made of an organic insulating material with a low dielectric constant of 1˜3. For example, the touch buffer film T-BUF may be formed of an acrylic-based, epoxy-based, or siloxan-based material. As the display device 100 is bent, the encapsulation layer ENCAP may be damaged and the touch sensor metal located on the touch buffer layer T-BUF may be broken. Even if the display device 100 is bent, the touch buffer film T-BUF, which is made of an organic insulating material and has a flattening performance, may prevent or at least reduce damage to the encapsulation layer ENCAP and/or cracking of the metals (e.g., TSM, BRG) constituting the touch sensor TS.

The protection layer PAC may be disposed while covering the touch sensor TS. The protection layer PAC may be an organic insulating film.

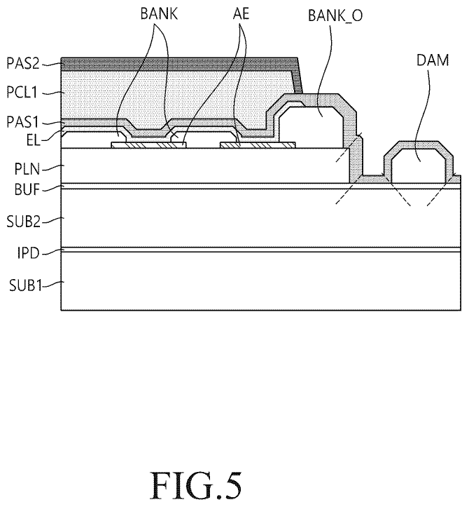

FIG. 5 is a cross-sectional view of a dam area of a display device 100 according to one or more embodiments of the present disclosure. Among the structural features of the display panel 110 shown in FIG. 5, there may be omitted descriptions of features that are the same as those of the display panel 110 shown in FIG. 4.

A first substrate SUB1 may be disposed at the bottom of the display panel 110. The first substrate SUB1 may be the same as the first substrate SUB1 shown in FIG. 4.

An interlayer insulating film IPD may be disposed on the first substrate SUB1. The interlayer insulating film IPD may be the same as the interlayer insulating film IPD shown in FIG. 4.

A second substrate SUB2 may be disposed on the interlayer insulating film IPD. The second substrate SUB2 may be the same as the second substrate SUB2 shown in FIG. 4.

A buffer layer BUF may be disposed on the second substrate SUB2. The buffer layer BUF may include a multi-buffer layer MBUF and active buffer layers ABUF1 and ABUF2 shown in FIG. 4.

A planarization layer PLN may be disposed on the buffer layer BUF. The planarization layer PLN may include the planarization layer PLN shown in FIG. 4. The planarization layer PLN may be composed of two or three or more planarization layers. The planarization layer may include a contact hole, and the upper and lower electrodes may be electrically connected through the contact hole.

An anode electrode AE may be disposed on the planarization layer PLN. The planarization layer PLN may include a plurality of transistors, and the plurality of transistors may include driving transistors. The source electrode (or drain electrode) of the driving transistor may be electrically connected to the anode electrode AE. The anode electrode AE shown in FIG. 5 may have the same characteristics as the anode electrode AE shown in FIG. 4. It will be omitted, for convenience of explanation, the configuration of the transistor electrically connected to the anode electrode AE shown in FIG. 5.

A bank BANK may be disposed on the planarization layer PLN and the anode electrode AE.

An outermost bank BANK_O may be disposed on the planarization layer PLN, and may be disposed adjacent to the end of the planarization layer PLN. The outermost bank BANK_O may prevent the organic encapsulation layer from overflowing to the outside.

A dam DAM may be disposed on the buffer layer BUF. The dam may prevent the organic encapsulation layer from overflowing to the outside. The dam DAM may be disposed spaced apart from the outermost bank BANK_O.

A light emission layer EL may be disposed on the bank BANK. The emission layer EL may be disposed on the bank BANK and in contact with the anode electrode AE. Referring to FIG. 5, the emission EL may be disposed in contact with two anode electrodes AE. A cathode electrode (not shown) may be disposed on the emission layer EL.

A first encapsulation layer PAS1 may be disposed to cover the emission layer EL, the outermost bank BANK_O, and the dam DAM. The first encapsulation layer PAS1 may be an inorganic encapsulation layer. The first encapsulation layer PAS1 may be deposited on the entire surface from the display area to the non-display area.

A second encapsulation layer PCL1 may be disposed on the first encapsulation layer PAS1. The second encapsulation layer PCL1 may be an organic encapsulation layer. The second encapsulation layer PCL1 may be thicker than the first encapsulation layer PAS1 and a third encapsulation layer PAS2.

The third encapsulation layer PAS2 may be disposed to cover the second encapsulation layer PCL1 and the first encapsulation layer PAS1. The third encapsulation layer PAS2 may be an inorganic encapsulation layer.

Meanwhile, when a specific layer is formed, the lower portion of the specific layer may be formed to be close to a right angle. This may be called a “high taper form.”

An area where the high taper shape is formed may be a high taper area.

When a high taper shape is formed, a seam shape may be generated in other layers disposed in the high taper area.

The step coverage may refer to the difference in thickness between the top and bottom layers of the uneven surface where deposition is performed, or the thickness difference between the top layer and the sidewall layer. The seam shape may be a shape that reduces step coverage during the manufacturing process of the display panel 110. For example, the display panel 110 may include a structure having a specific shape, such as a taper. Another layer may be disposed on top of the structure having a specific shape, such as a taper. If the taper is formed unstable, the layer deposited on top of the tapered structure may be unstable. If the layer deposited on the tapered structure is unstable, cracks may occur in the layer, which can be called a “seam.”

For example, a seam may be created in the lower layer of a high taper shape. Referring to FIG. 5, the seam is indicated by a dotted line.

Moisture may penetrate through the seam shape and damage the display device 100.

Accordingly, embodiments of the present disclosure may provide a display device 100 capable of preventing or at least reducing moisture penetration.

Embodiments of the present disclosure may provide a display device 100 capable of preventing, reducing, or delaying the penetration of moisture into the display panel from the outside by a seam which may be formed in the display panel 110.

Embodiments of the present disclosure may provide a display device 100 with improved encapsulation performance by forming a long moisture permeable path.

Embodiments of the present disclosure may provide a display device 100 capable of low power consumption by preventing or at least reducing moisture penetration.

The display device 100 will be described in detail below.

FIG. 6 is a cross-sectional view of a dam area of a display device 100 according to one or more embodiments of the present disclosure.

Referring to FIG. 6, a first substrate SUB1 may be disposed at the lowest portion of the display panel 110. The first substrate SUB1 may be the same as the first substrate SUB1 shown in FIG. 4.

Referring to FIG. 6, an interlayer insulating film IPD may be disposed on the first substrate SUB1. The interlayer insulating film IPD may be the same as the interlayer insulating film IPD shown in FIG. 4.

Referring to FIG. 6, a second substrate SUB2 may be disposed on the interlayer insulating film IPD. The second substrate SUB2 may be the same as the second substrate SUB2 shown in FIG. 4.

Referring to FIG. 6, a buffer layer BUF may be disposed on the second substrate SUB2. The buffer layer BUF may include a multi-buffer layer MBUF and active buffer layers ABUF1 and ABUF2 shown in FIG. 4.

Referring to FIG. 6, a planarization layer PLN may be disposed on the buffer layer BUF. The planarization layer PLN may include the planarization layer PLN shown in FIG. 4. The planarization layer PLN may be composed of two or three or more planarization layers PLN.

The planarization layer PLN may include an end formed with a high taper. Seams may be generated in the lower layer of the high taper area of the planarization layer PLN. That is, the lower layer of the high taper area of the planarization layer PLN may include a seam. For example, referring to FIG. 6, a seam may be formed in the buffer layer.

Referring to FIG. 6, an anode electrode AE may be disposed on the planarization layer PLN. There will be omitted, for convenience of explanation, the configuration of the transistor electrically connected to the anode electrode AE shown in FIG. 6. A cathode electrode (not shown) may be disposed on an emission layer EL.

Referring to FIG. 6, a bank BANK may be disposed on the planarization layer PLN and the anode electrode AE.

Referring to FIG. 6, the outermost bank BANK_O may be disposed on the planarization layer PLN, and may be disposed adjacent to the end of the planarization layer PLN. The height of an upper surface of the outermost bank BANK_O may be greater than that of the other banks BANK. The outermost bank BANK_O may prevent the organic encapsulation layer from overflowing to the outside.

The outermost bank BANK_O may include an end formed with a high taper. A seam may be generated in the lower layer of the high taper area of the outermost bank BANK_O. That is, the lower layer of the high taper area of the outermost bank BANK_O may include a seam. For example, referring to FIG. 6, a seam may be formed in the planarization layer.

Referring to FIG. 6, a dam DAM may be disposed on the buffer layer BUF. The dam may prevent the organic encapsulation layer from overflowing to the outside.

The height of the dam DAM may be similar to the height of the planarization layer PLN. In this case, the dam DAM and the planarization layer PLN may include the same components.

The dam DAM may be disposed spaced apart from the planarization layer PLN. An organic encapsulation layer may be disposed between the dam DAM and the planarization layer PLN.

The dam DAM may include an end formed with a high taper. A seam may be generated in the lower layer of the high taper area of the dam. That is, the lower layer of the high taper area of the DAM may include a seam. For example, referring to FIG. 6, a seam may be formed in the buffer layer.

Referring to FIG. 6, an emission layer EL may be disposed on the bank BANK. The emission layer EL may be disposed on the bank BANK and in contact with the anode electrode AE.

Referring to FIG. 6, a first encapsulation layer PAS1 may be disposed to cover the emission layer EL, the outermost bank BANK_O, and the dam DAM. The first encapsulation layer PAS1 may be an inorganic encapsulation layer.

Referring to FIG. 6, a first coating layer FCL1 may be disposed on the first encapsulation layer PAS1, and may be disposed in the dam area. As the first coating layer FCL1 is disposed in the dam area, the first coating layer FCL1 may be disposed to cover the high taper area. The dam area may include an area where a dam DAM and the outermost bank BANK_O are disposed.

Referring to FIG. 6, the first coating layer FCL1 may be disposed to cover the outermost bank BANK_O, the planarization layer PLN, the buffer layer BUF and the dam DAM.

The first coating layer FCL1 may be disposed outside the lower portion of the planarization layer PLN. The first coating layer FCL1 may be disposed to overlap the planarization layer PLN. When the planarization layer PLN is formed with a high taper, a seam may be generated in the planarization layer PLN. The first encapsulation layer PAS1 and the first coating layer FCL1 may be disposed in an area where a seam may occur in the planarization layer PLN.

The first coating layer FCL1 may be disposed outside of the lower portion of the bank BANK. The first coating layer FCL1 may be disposed to overlap the bank BANK. When the bank BANK is formed with a high taper, a seam may be generated in the bank BANK. The first encapsulation layer PAS1 and the first coating layer FCL1 may be disposed in an area where a seam may occur in the bank BANK.

The first coating layer FCL1 may be disposed outside the inner lower portion of the dam DAM. The first coating layer FCL1 may be disposed to overlap the dam DAM. If the dam DAM is formed with a high taper, a seam may be generated in the dam DAM. The first encapsulation layer PAS1 and the first coating layer FCL1 may be disposed in an area where a seam may occur in the dam DAM.

The display panel 110 may include four bezel areas on the top, bottom, left, and right. The dam DAM may be disposed in at least three bezel areas. The first coating layer FCL1 disposed in the dam area may also be disposed in at least three bezel areas.

Referring to FIG. 6, the first coating layer FCL1 may be disposed to overlap a portion of the outermost bank BANK_O, a side of the planarization layer PLN, an upper surface of the buffer layer BUF, and an inner surface of the dam DAM.

Referring to FIG. 6, a first portion of the first coating layer FCL1 overlapping with the upper surface of the outermost bank BANK_O may be disposed higher than a second portion of the first coating layer FCL1 overlapping with the upper surface of the dam DAM. The second portion of the first coating layer FCL1 overlapping the upper surface of the dam DAM may be disposed higher than a third portion of the first coating layer FCL1 overlapping the buffer layer BUF.

The first coating layer FCL1 may include a fluorine-based component. Fluorine-based components may have characteristics that separate them from moisture, that is, hydrophobic properties. Accordingly, the first coating layer FCL1 containing a fluorine-based component may effectively block moisture.

The first coating layer FCL1 containing a fluorine-based component may be patterned or dissolved only by a fluorine-based material, and may be not dissolved by a general organic solvent. Therefore, when the first coating layer FCL1 containing a fluorine-based component is formed, the display panel 110 may not be deteriorated by the fluorine-based solvent.

Fluorine-based components may be in the form of polymers containing various amounts of fluorine (F) based on a carbon-carbon backbone.

Fluorine-based solvents may be single molecules or complexes containing a large number of fluorine (F) based on a carbon-carbon backbone.

Referring to FIG. 6, the first coating layer FCL1 may be disposed inside the dam DAM.

Referring to FIG. 6, a second coating layer FCL2 may be disposed outside the dam DAM.

Referring to FIG. 6, the second coating layer FCL2 may be disposed outside an outer lower portion of the dam DAM. The second coating layer FCL2 may be disposed to overlap the dam DAM. If the dam DAM is formed with a high taper, a seam may be generated in the dam DAM. The first encapsulation layer PAS1 and the first coating layer FCL1 may be disposed in an area where a seam may occur in the dam DAM.

The second coating layer FCL2 may be disposed to overlap an upper surface of the buffer layer BUF and an outer surface of the dam DAM.

The second coating layer FCL2 may include a fluorine-based component. The characteristics of the second coating layer FCL2 containing a fluorine-based component are the same as those of the first coating layer FCL1 containing a fluorine-based component.

The height of the first coating layer FCL1 overlapping the buffer layer BUF may be the same as the height of the second coating layer FCL2 overlapping the buffer layer BUF.

Since the first coating layer FCL1 and the second coating layer FCL2 are disposed to overlap an area where the seam may be formed, it is possible to prevent or at least reduce moisture from penetrating into the display panel 110.

Referring to FIG. 6, the first coating layer FCL1 and the second coating layer FCL2 may be disposed to be spaced apart from each other. A third encapsulation layer PAS2 may be disposed between the first coating layer FCL1 overlapping the dam DAM and the second coating layer FCL2 overlapping the dam DAM. However, the first coating layer FCL1 and the second coating layer FCL2 may be disposed integrally.

The first coating layer FCL1 containing a fluorine-based component may protect a seam, which may occur in the outermost bank BANK_O, the planarization layer PLN and buffer layer BUF, from external moisture.

The second coating layer FCL2 containing a fluorine-based component may protect a seam, which may occur in the buffer layer BUF, from external moisture.

Referring to FIG. 6, a second encapsulation layer PCL1 may be disposed on the first encapsulation layer PAS1. The second encapsulation layer PCL1 may be an organic encapsulation layer.

Referring to FIG. 6, a third encapsulation layer PAS2 may be disposed on the second encapsulation layer PCL1. The third encapsulation layer PAS2 may be an inorganic encapsulation layer.

Referring to FIG. 6, a fourth encapsulation layer PCL2 may be disposed between the first coating layer FCL1 and the third encapsulation layer PAS2. The fourth encapsulation layer PCL2 may be an organic encapsulation layer.

The fourth encapsulation layer PCL2 may be disposed between the dam DAM and the outermost bank BANK_O.

The fourth encapsulation layer PCL2 may be disposed at a location spaced apart from the second encapsulation layer PCL1.

The fourth encapsulation layer PCL2 may be formed together with the second encapsulation layer PCL1.

Referring to FIG. 6, a fifth encapsulation layer PAS3 may be disposed on the fourth encapsulation layer PCL2. The fifth encapsulation layer PAS3 may be disposed to be spaced apart from the third encapsulation layer PAS2.

Referring to FIG. 6, the height of an upper surface of the fourth encapsulation layer PCL2 may be greater than the height of an upper surface of the dam DAM.

The height of an upper surface of the fourth encapsulation layer PCL2 may be smaller than the height of the outermost bank BANK_O.

Since the fourth encapsulation layer PCL2 is disposed to be spaced apart from the second encapsulation layer PCL1, a length of moisture permeable path through which external moisture reaches the second encapsulation layer PCL1 may be increased. That is, since the fourth encapsulation layer PCL2 is disposed to be spaced apart from the second encapsulation layer PCL1, there may be improved the moisture permeation reliability.

In addition, as the fourth encapsulation layer PCL2 is disposed between the dam DAM and the outermost bank BANK_O, there may more robustly protect the area where the seam may be formed. Accordingly, it is possible to prevent or at least reduce the moisture from penetrating into the display panel 110.

The fourth encapsulation layer PCL2 may be disposed between the dam DAM and the outermost bank BANK_O, and may be disposed to cover the first coating layer FCL1. This will be described with reference to FIG. 7.

FIG. 7 is a cross-sectional view of a dam area of a display device 100 according to one or more embodiments of the present disclosure.

Referring to FIG. 7, an anode electrode AE may be disposed on the planarization layer PLN. There is omitted, for convenience of explanation, the description for the configuration of the transistor electrically connected to the anode electrode AE shown in FIG. 7. A cathode electrode (not shown) may be disposed on an emission layer EL.

Referring to FIG. 7, a fourth encapsulation layer PCL2 may be disposed between the dam DAM and the outermost bank BANK_O, and may be disposed to cover a first coating layer FCL1.

The fourth encapsulation layer PCL2 may be disposed at a location spaced apart from the second encapsulation layer PCL1.

The fourth encapsulation layer PCL2 may be disposed in contact with the first encapsulation layer PAS1 overlapping the outermost bank BANK_O.

The fourth encapsulation layer PCL2 may be disposed in contact with the first encapsulation layer PAS1 overlapping the dam DAM.

Referring to FIG. 7, a third encapsulation layer PAS2 may be disposed to cover the second encapsulation layer PCL1, and the fifth encapsulation layer PAS3 may be disposed to cover the fourth encapsulation layer PCL2. The third encapsulation layer PAS2 and the fifth encapsulation layer PAS3 may be inorganic encapsulation layers.

The third encapsulation layer PAS2 and the fifth encapsulation layer PAS3 may be disposed to be spaced apart from each other.

Referring to FIG. 7, the fifth encapsulation layer PAS3 may be disposed in contact with the first encapsulation layer PAS1 overlapping the outermost bank BANK_O.

The fifth encapsulation layer PAS3 may be disposed in contact with the first encapsulation layer PAS1 overlapping the dam DAM.

Referring to FIG. 7, the fourth encapsulation layer PCL2 and the fifth encapsulation layer PAS3 may be disposed between the first coating layer FCL1 overlapping with the dam DAM and the second coating layer FCL2 overlapping with the dam DAM.

Referring to FIG. 7, the fourth encapsulation layer PCL2 and the fifth encapsulation layer PAS3 may be disposed on the outside of the display area. The fourth encapsulation layer PCL2 and the fifth encapsulation layer PAS3 may be arranged to surround the display area. The fourth encapsulation layer PCL2 and the fifth encapsulation layer PAS3 may be disposed on the outside of at least three sides of the display area.

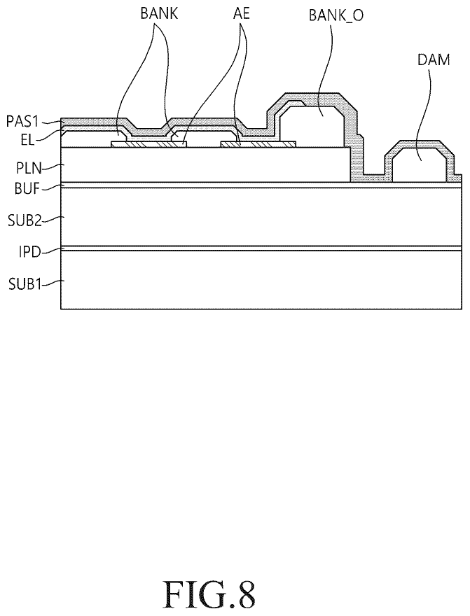

FIGS. 8, 9 and 10 are diagrams for explaining the process of forming a coating layer according to one or more embodiments of the present disclosure.

Referring to FIG. 8, there are illustrated a first substrate SUB1, an interlayer insulating film IPD, a second substrate SUB2, a buffer layer BUF, a planarization layer PLN, a dam DAM, an anode electrode AE, a bank BANK, the outermost bank BANK_O, and a first encapsulation layer PAS1.

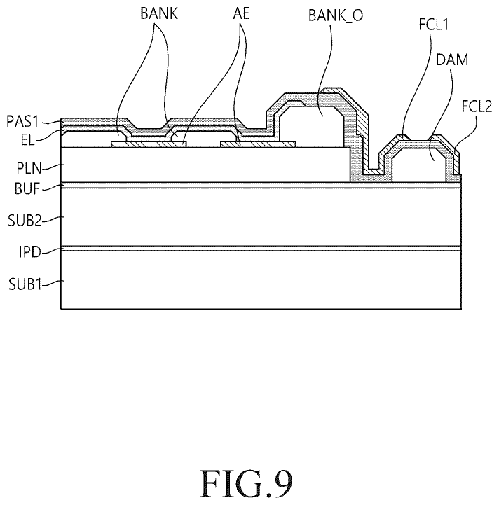

Referring to FIG. 9, a first coating layer FCL1 may be disposed on the first encapsulation layer PAS1 overlapping the outermost bank BANK.

Referring to FIG. 9, the first coating layer FCL1 may be disposed on the first encapsulation layer PAS1 overlapping the dam DAM.

Referring to FIG. 9, the first coating layer FCL1 may be disposed on the first encapsulation layer PAS1 overlapping the planarization layer PLN.

Referring to FIG. 9, the first coating layer FCL1 may be disposed on the first encapsulation layer PAS1 overlapping the buffer layer BUF.

Referring to FIG. 9, a second coating layer FCL2 may be disposed on the first encapsulation layer PAS1 overlapping the dam DAM.

Referring to FIG. 9, the second coating layer FCL2 may be disposed on the first encapsulation layer PAS1 overlapping the buffer layer BUF.

Referring to FIG. 9, the first coating layer FCL1 may be disposed inside the dam DAM, and the second coating layer FCL2 may be disposed outside the dam DAM.

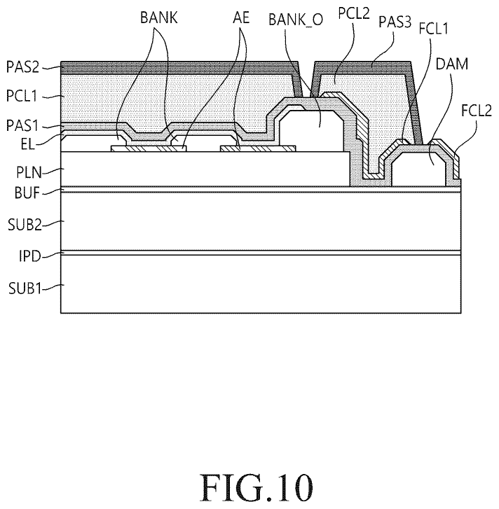

Referring to FIG. 10, a second encapsulation layer PCL1 may be disposed on the first encapsulation layer PAS1.

Referring to FIG. 10, the second encapsulation layer PCL1 may be disposed to overlap an emission layer EL.

Referring to FIG. 10, the second encapsulation layer PCL1 may be disposed in the display area.

Referring to FIG. 10, the second encapsulation layer PCL1 may be disposed to overlap the outermost bank BANK_O.

Referring to FIG. 10, a third encapsulation layer PAS2 may be disposed on the second encapsulation layer PCL1.

Referring to FIG. 10, the third encapsulation layer PAS2 may be arranged to overlap the outermost bank BANK_O.

Referring to FIG. 10, a fourth encapsulation layer PCL2 may be disposed to cover the first coating layer FCL1.

Referring to FIG. 10, the fourth encapsulation layer PCL2 may be disposed to overlap the outermost bank BANK_O.

Referring to FIG. 10, the fourth encapsulation layer PCL2 may be disposed to overlap the dam DAM.

Referring to FIG. 10, the fourth encapsulation layer PCL2 may be disposed to be spaced apart from the second encapsulation layer PCL1.

Referring to FIG. 10, a fifth encapsulation layer PAS3 may be disposed on the fourth encapsulation layer PCL2.

Referring to FIG. 10, the fifth encapsulation layer PAS3 may be arranged to overlap the outermost bank BANK_O.

Referring to FIG. 10, the fifth encapsulation layer PAS3 may be arranged to overlap the dam DAM.

Referring to FIG. 10, the fifth encapsulation layer PAS3 may be disposed to be spaced apart from the third encapsulation layer PAS2.

Embodiments of the present disclosure described above are briefly described as follows.

A display device according to one or more embodiments of the present disclosure may include a substrate including a display area, and a dam area which is an outer area of the display area, a planarization layer disposed on the substrate, a dam disposed on the substrate and disposed in the dam area, a first encapsulation layer disposed to cover the planarization layer and the dam, and a first coating layer disposed on the first encapsulation layer and in the dam area.

The first coating layer may be disposed outside a lower portion of the planarization layer.

The first coating layer may be disposed outside an inner lower portion of the dam.

The display device may further include a bank disposed between the first encapsulation layer and the planarization layer, and the first coating layer may be disposed outside a lower portion of the bank.

The display device may further include a second coating layer disposed outside a lower portion of the dam.

The first coating layer may be disposed inside the dam, and the second coating layer may be disposed outside the dam.

The display device may further include a second encapsulation layer disposed on the first encapsulation layer, a third encapsulation layer disposed on the second encapsulation layer, and a fourth encapsulation layer disposed between the first coating layer and the third encapsulation layer. The fourth encapsulation layer may be disposed to cover the first coating layer.

The display device may further include a fifth encapsulation layer which is disposed to cover the fourth encapsulation layer and is an inorganic encapsulation layer. In this case, the third encapsulation layer may be disposed to cover the second encapsulation layer which is an organic encapsulation layer, and the third encapsulation layer may be an inorganic encapsulation layer.

The first coating layer may include a fluorine-based materail.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device, comprising:
a substrate;
a planarization layer on the substrate;
a dam separated from the planarization layer;
a first encapsulation layer that covers the dam; and
a first coating layer on the first encapsulation layer, the first coating layer overlaps the dam.

2. The display device of claim 1, further comprising:
a bank on the planarization layer, an outermost bank of the bank adjacent to an end of the planarization layer, and the dam is separated from the outermost bank,
wherein the first encapsulation layer covers the outermost bank, and the first coating layer overlaps the outermost bank.

3. The display device of claim 2, further comprising:
a buffer layer on the substrate, wherein the planarization layer and the dam are on the buffer layer;
a first electrode on the planarization layer; and
a light emission layer on the bank, the light emission layer in contact with the first electrode, and the first encapsulation layer covers the light emission layer.

4. The display device of claim 3, wherein the first coating layer overlaps an outer surface of the outermost bank, a side of the planarization layer, an upper surface of the buffer layer, and an inner surface of the dam.

5. The display device of claim 1, wherein the substrate comprises a display area and four bezel areas that surround the display area, and
wherein the dam and the first coating layer are in at least three bezel areas of the four bezel areas.

6. The display device of claim 2, wherein a height of the outermost bank is greater than a height of remaining banks of the bank.

7. The display device of claim 3, wherein a first height of a first portion of the first coating layer that overlaps the outermost bank is greater than a second height of a second portion of the first coating layer that overlaps the dam, and the second height is greater than a third height of a third portion of the first coating layer that overlaps the buffer layer.

8. The display device of claim 3, further comprising:
a second coating layer that overlaps an upper surface of the buffer layer and an outer surface of the dam.

9. The display device of claim 8, where a first height of a portion of the first coating layer that overlaps the buffer layer is a same as a second height of a portion of the second coating layer that overlaps the buffer layer.

10. The display device of claim 8, wherein the first coating layer and the second coating layer are separated from each other.

11. The display device of claim 8, wherein the first coating layer and the second coating layer include fluoro-based components.

12. The display device of claim 8, further comprising:
a second encapsulation layer on the first encapsulation layer; and
a third encapsulation layer on the second encapsulation layer.

13. The display device of claim 12, wherein the third encapsulation layer is between a portion of the first coating layer that overlaps the dam and a portion of the second coating layer that overlaps the dam.

14. The display device of claim 12, further comprising:
a fourth encapsulation layer between the dam and the outermost bank.

15. The display device of claim 14, wherein the fourth encapsulation layer is between the first coating layer and the third encapsulation layer.

16. The display device of claim 14, wherein the fourth encapsulation layer is separated from the second encapsulation layer.

17. The display device of claim 14, wherein a height of an upper surface of the fourth encapsulation layer is greater than a height of an upper surface of the dam.

18. The display device of claim 14, wherein the fourth encapsulation layer is in contact with a first portion of the first encapsulation layer that overlaps the outermost bank and a second portion of the first encapsulation layer that overlaps the dam.

19. The display device of claim 14, further comprising:
a fifth encapsulation layer on the fourth encapsulation layer.

20. The display device of claim 19, wherein the fifth encapsulation layer is separated from the third encapsulation layer.

21. The display device of claim 19, wherein the fifth encapsulation layer is in contact with a first portion of the first encapsulation layer that overlaps the outermost bank and a second portion of the first encapsulation layer that overlaps the dam.

22. The display device of claim 19, wherein the fourth encapsulation layer and the fifth encapsulation layer are between a portion of the first coating layer that overlaps the dam and a portion of the second coating layer that overlaps the dam.

23. The display device of claim 2, wherein lower parts of the planarization layer, the outermost bank and the dam are at right angles relative to a layer stacking direction.

24. A display device, comprising:
a substrate comprising a display area and a bezel area around the display area;
a dam area in the bezel area, the dam area comprises a dam;
a first encapsulation layer on the substrate, the first encapsulation layer covers the dam area; and
a first coating layer that covers the first encapsulation layer and overlaps the dam.
